(19) United States
(12) Patent Application Publication
(10) Pub. No.: US 2022/0299553 A1
(43) Pub. Date: Sep. 22, 2022

(54) Self-attenuated energy harvesting antenna

(71) Applicant: Geo Tag IP LLC, Austin, TX (US)

(72) Inventor: Steve Puccini, Chicago, IL (US)

(21) Appl. No.: 17/695,777

(22) Filed: Mar. 15, 2022

Related U.S. Application Data
(60) Provisional application No. 63/161,938, filed on Mar. 16, 2021.

(51) Int. Cl. G01R 29/10; H01Q 1/24; H04Q 9/00

(52) U.S. Cl. CPC G01R 29/10; H01Q 1/24; H04Q 9/00; H04Q 2209/886

(57) ABSTRACT

The present invention relates to a harvesting antenna, specifically one that harvests ambient energy of the breadth of the electromagnetic spectrum concurrently. In a preferred embodiment, this is accomplished with an apparatus comprising meta materials, conductive inks, and thin films. The process of collection comprises modern additive manufacturing processes, spectral modeling software, computer aided isotropic Mandelbrot fractal pattern printing design and further application of computing and physics.

### CROSS-REFERENCE TO RELATED APPLICATIONS

The present application claims the benefit of priority to US Provisional Patent Application 63/161,938 filed Mar. 15, 2021, with first named inventor Steve Puccini.

### TECHNICAL FIELD

The present invention relates to an energy harvesting antenna.

### BACKGROUND

Antennae are needed to receive and broadcast information, though the ever increasing need to get them smaller is hampered by obtaining power sources for energy. As such, an energy harvesting antenna would serve a need in the space of information sharing.

### SUMMARY

The present invention relates to a harvesting antenna, specifically one that harvests ambient energy of the breadth of the electromagnetic spectrum concurrently. In a preferred embodiment, this is accomplished with an apparatus comprising meta materials, conductive inks, and thin films. The process of collection comprises modern additive manufacturing processes, spectral modeling software, computer aided isotropic Mandelbrot fractal pattern printing design and further application of computing and physics.

### BRIEF DESCRIPTION OF FIGURES

FIG. 1 is a graphic used to explain Fresnel's Equations.

FIG. 2 is a block diagram of an embodiment of an antenna as described herein.

### DETAILED DESCRIPTION

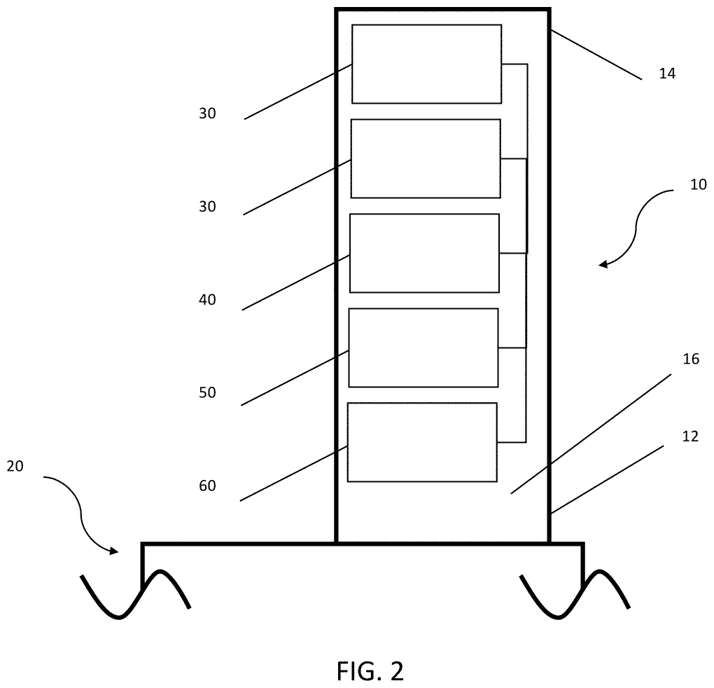

As shown in FIG. 2, the present embodiment comprises a harvesting antenna 10, comprising a body 16 with a first 12 and second end 14, wherein the first end 12 is configured to affix to a secondary body 20. The antenna body 16 may be of any length or cross-sectional size or shape sufficient to the purposes described herein.

The antenna body 16 may further comprise one or more sensors 30. These one or more sensors 30 may include one or more selected from the group of a biological lab chip, electrochemical sensor, electrothermal sensor, thermochemical sensor, optic sensor, microfluidic sensor, spectral sensor, gas volumetric sensor, liquid volumetric sensor, and an accelerometer. The antenna body 16 may comprise a single sensor 30, multiple sensors 30 of the same type, or a combination of sensors 30. The sensors 30 may communicate with one another, along with a processor 60, creating logic gates and conditions.

These sensors 30 and antenna 10 are then powered to collect the information required by an end user. The power may come from one or more power sources 40 selected from the group of an external power source, ambient or isotype, harvested/stored power bank, a capacitor with or without regulation, field effect passive, and radar. The power source 40 may power a processor 60.

The antenna body may further comprise alerts and defense features 50. This defense mechanism 50 may be of any type that can be used to alert a user of malfunctioning or tampering of the device 10. The defense mechanism 50 may be a voltage discharge, an audible sound, xenon gas discharge (plasmatic or otherwise), optical or via light, or a radio frequency discharge. The defense mechanism 50 may further be a combination of one or more of these. The defense mechanism 50 may be powered by the same power source 40 powering the sensors 30 and antenna 10, or a distinct power source 40.

The frequencies put off and collected by the antenna 10 and can be calculated via Fresnel's Equations. Fresnel's equations describe the reflection and transmission of electromagnetic waves at an interface. That is, they give the reflection and transmission coefficients for waves parallel and perpendicular to the plane of incidence. For a dielectric medium where Snell's Law can be used to relate the incident and transmitted angles, Fresnel's Equations can be stated in terms of the angles of incidence and transmission.

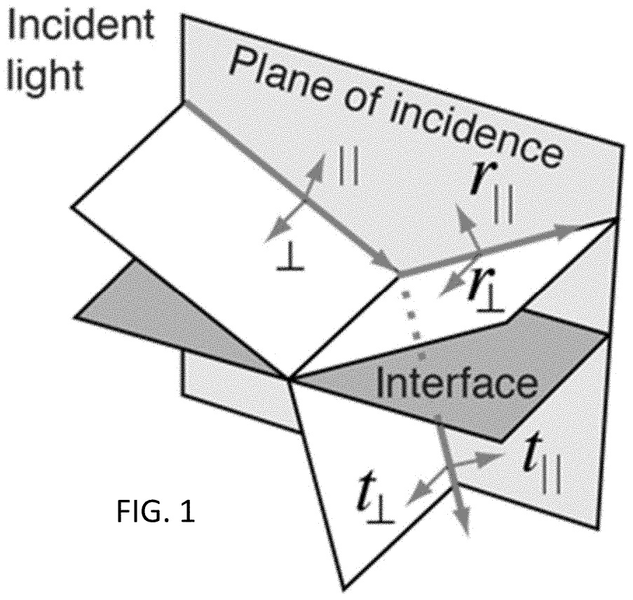

The equations using the FIG. 1 for variables are as follows

$$s - polarized light : \\ {r}_{⊥} = \frac{{n}_{i} cos ( {θ}_{i} ) - {n}_{i} cos ( {θ}_{i} )}{{n}_{i} cos ( {θ}_{i} ) + {n}_{i} cos ( {θ}_{i} )} \\ {t}_{⊥} = \frac{2 {n}_{i} cos ( {θ}_{i} )}{{n}_{i} cos ( {θ}_{i} ) + {n}_{i} cos ( {θ}_{i} )}$$

$$p - polarized light : \\ {r}_{\vert \vert} = \frac{{n}_{i} cos ( {θ}_{i} ) - {n}_{i} cos ( {θ}_{i} )}{{n}_{i} cos ( {θ}_{i} ) + {n}_{i} cos ( {θ}_{i} )} \\ {t}_{\vert \vert} = \frac{2 {n}_{i} cos ( {θ}_{i} )}{{n}_{i} cos ( {θ}_{i} ) + {n}_{i} cos ( {θ}_{i} )}$$

Using these equations, along with using Brewster's Angle, the antenna body 16 in combination with a processor 60 can take the received information and harvest ambient energy of the breadth of the electromagnetic spectrum concurrently. In a preferred embodiment, this is accomplished with an antenna body 16 comprising meta materials, conductive inks, and thin films. The process of collection comprises modern additive manufacturing processes, spectral modeling software, computer aided isotropic Mandelbrot fractal pattern printing design and further application of computing and physics. This process can be described as the article, “Harvesting Energy From the Air: Metasurface-Based Antenna Turns Ambient Radio Waves Into Electric Power,” published at https://scitechdaily.com/harvesting-energy-from-the-air-metasurface-based-antenna-turns-ambient-radio-waves-into-electric-power/, on Mar. 6, 2022, which is herein incorporated by reference.

Although the present invention has been illustrated and described herein with reference to preferred embodiments and specific examples thereof, it will be readily apparent to those of ordinary skill in the art that the other embodiments and examples may perform similar functions and/or achieve like results. All such equivalent embodiments and examples are within the spirit and scope of the present invention, are contemplated thereby, and are intended to be covered by the following claims.

The terminology used herein is for the purpose of describing particular embodiments only and is not intended to be limiting of the invention. As used herein, the term“and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the invention, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

Although a preferred embodiment of this invention has been disclosed, a worker of ordinary skill in this art would recognize that certain modifications would come within the scope of this invention. For that reason, the following claims should be studied to determine the true scope and content of this invention.

1. An energy harvesting antenna, comprising:
an antenna body, with a first and second end, with the first end capable of integrating with a second body;
a sensor within the antenna body;
a power source;
a processor coupled to the sensor and power source;
wherein the antenna broadcasts and captures a frequency capable of harvest energy from the ambient air surrounding the antenna body.

2. The antenna of claim 1, wherein the antenna body comprises meta materials, conductive inks, or thin films.

3. The antenna of claim 1, further comprising a plurality of power sources internal to the antenna body.

4. The antenna of claim 1, further comprising an alert or defensive feature.

5. The antenna of claim 1, further comprising a plurality of sensors configured to define logic gates depending on results from one sensor in relation to the other.

6. The antenna of claim 4, wherein the alert or defensive feature is powered by the same power source as the sensor and processor.

7. The antenna of claim 4, further comprising a second power source, wherein the second power source powers only the alert or defensive feature.

8. The antenna of claim 4, wherein the alert or defensive feature is selected from the group of voltage discharge, an audible sound, xenon gas discharge (plasmatic or otherwise), optical or via light, or a radio frequency discharge.

9. The antenna of claim 4, wherein the alert or defensive feature is triggered upon a sensor detecting a malfunction.

10. The antenna of claim 4, wherein the alert or defensive feature is triggered upon a sensor detecting tampering with the antenna or second body.

11. The antenna of claim 1, wherein the sensor is selected from the group of biological lab chip, electrochemical sensor, electrothermal sensor, thermochemical sensor, optic sensor, microfluidic sensor, spectral sensor, gas volumetric sensor, liquid volumetric sensor, and an accelerometer.
